(19) United States
(12) Patent Application Publication
(10) Pub. No.: US 2013/0234178 A1
(43) Pub. Date: Sep. 12, 2013

(54) SEMICONDUCTOR LIGHT EMITTING DEVICE AND METHOD FOR MANUFACTURING THE SAME

(71) Applicants: Satoshi Mitsugi, Kanagawa-ken (JP); Naoharu Sugiyama, Kanagawa-ken (JP); Taisuke Sato, Kanagawa-ken (JP); Shinya Nunoue, Chiba-ken (JP)

(72) Inventors: Satoshi Mitsugi, Kanagawa-ken (JP); Naoharu Sugiyama, Kanagawa-ken (JP); Taisuke Sato, Kanagawa-ken (JP); Shinya Nunoue, Chiba-ken (JP)

(73) Assignee: Kabushiki Kaisha Toshiba, Tokyo (JP)

(21) Appl. No.: 13/601,015

(22) Filed: Aug. 31, 2012

(30) Foreign Application Priority Data
Feb. 1, 2012 (JP) 2012-020249

(51) Int. Cl. H01L 33/60

(52) U.S. Cl. CPC H01L 33/60
USPC 257/94; 438/29

(57) ABSTRACT

According to one embodiment, a semiconductor light emitting device includes a silicon substrate, a buffer layer, a foundation semiconductor layer, a first semiconductor layer, a light emitting unit and a second semiconductor layer. The buffer layer is provided on a part of a major surface of the silicon substrate. The foundation semiconductor layer is crystal-grown from an upper surface of the buffer layer, covers a non-formed region of the major surface where the buffer layer is not provided, and is spaced apart from the non-formed region. The first semiconductor layer is provided on the foundation semiconductor layer and has a first conductivity type. The light emitting unit is provided on the first semiconductor layer. The second semiconductor layer is provided on the light emitting unit and has a second conductivity type.

### CROSS-REFERENCE TO RELATED APPLICATIONS

This application is based upon and claims the benefit of priority from the prior Japanese Patent Application No. 2012-020249, filed on Feb. 1, 2012; the entire contents of which are incorporated herein by reference.

### FIELD

Embodiments described herein relate generally to a semiconductor light emitting device and a method for manufacturing the same.

### BACKGROUND

Various semiconductor light emitting devices using nitride semiconductors such as gallium nitride are developed. A semiconductor layer used in such a semiconductor light emitting device is mainly crystal-grown on a sapphire substrate or the like. In the semiconductor light emitting device, high efficiency and improved productivity are required.

### BRIEF DESCRIPTION OF THE DRAWINGS

FIG. 1 is a schematic sectional view showing a configuration of a semiconductor light emitting device according to a first embodiment;

FIG. 2 is a schematic sectional view showing a configuration of a part of the semiconductor light emitting device according to the first embodiment;

FIG. 3A to FIG. 3H are schematic sectional views showing the configuration of a part of the semiconductor light emitting device according to the first embodiment;

FIG. 4 is a schematic sectional view showing the configuration of another semiconductor light emitting device according to the first embodiment;

FIG. 5 is a schematic sectional view showing the configuration of another semiconductor light emitting device according to the first embodiment;

FIG. 6 is a graph showing characteristics of the semiconductor light emitting device according to the first embodiment;

FIG. 7 is a graph showing characteristics of the semiconductor light emitting device according to the first embodiment;

FIG. 8 is a graph showing characteristics of the semiconductor light emitting device according to the first embodiment;

FIG. 9 is a graph showing characteristics of the semiconductor light emitting device according to the first embodiment;

FIG. 10A to FIG. 10D are schematic sectional views showing the configuration of another semiconductor light emitting device according to the first embodiment;

FIG. 11 is a flow chart showing a method of manufacturing a semiconductor light emitting device according to the second embodiment;

FIG. 12 is a flow chart showing a part of the method of manufacturing a semiconductor light emitting device according to the second embodiment;

FIG. 13 is a schematic sectional view showing a part of the semiconductor light emitting device according to the second embodiment;

FIG. 14 is a flow chart showing a method of manufacturing a semiconductor light emitting device according to the second embodiment;

FIG. 15 is a schematic sectional view showing a part of the semiconductor light emitting device according to the second embodiment;

FIG. 16 is a graph showing characteristics of the semiconductor light emitting device according to the second embodiment;

FIG. 17 is a flow chart showing a part of the method of manufacturing a semiconductor light emitting device according to the second embodiment;

FIG. 18 is a schematic sectional view showing a part of the semiconductor light emitting device according to the second embodiment;

FIG. 19A to FIG. 19C are schematic views showing the configuration of a semiconductor light emitting device according to a third embodiment; and

FIG. 20A and FIG. 20B are schematic views showing the configuration of a semiconductor light emitting device according to a fourth embodiment.

### DETAILED DESCRIPTION

According to one embodiment, a semiconductor light emitting device includes a silicon substrate, a buffer layer, a foundation semiconductor layer, a first semiconductor layer, a light emitting unit and a second semiconductor layer. The silicon substrate has a major surface. The buffer layer is provided on a part of the major surface. The foundation semiconductor layer is crystal-grown from an upper surface of the buffer layer. The foundation semiconductor layer covers a non-formed region of the major surface where the buffer layer is not provided. The foundation semiconductor layer is spaced apart from the non-formed region. The first semiconductor layer is provided on the foundation semiconductor layer and has a first conductivity type. The light emitting unit is provided on the first semiconductor layer. The second semiconductor layer is provided on the light emitting unit and has a second conductivity type.

According to another embodiment, a method for manufacturing a semiconductor light emitting device is disclosed. The method can include forming a buffer layer on a part of a major surface of a silicon substrate. The method can include laterally crystal-growing a foundation semiconductor layer from an upper surface of the buffer layer. The foundation semiconductor layer covers a non-formed region where the buffer layer is not provided on the major surface. The foundation semiconductor layer is spaced apart from the non-formed region. The method can include crystal-growing a first semiconductor layer of a first conductivity type on the foundation semiconductor layer. The method can include crystal-growing a light emitting unit on the first semiconductor layer. In addition, the method can include crystal-growing a second semiconductor layer of a second conductivity type on the light emitting unit.

Various embodiments will be described hereinafter with reference to the accompanying drawings.

The drawings are schematic or conceptual, and relationships between the thicknesses and the widths of respective portions, ratios of the sizes of the portions, and the like are not always the same as those of actual ones. Even though the same portions are shown, the dimensions and the ratios of the portions in the drawings may be changed depending on the drawings.

In the specification and the drawings, the same reference symbols as in mentioned drawings denote the same elements in the drawings, and detailed description thereof will be arbitrarily omitted.

### First Embodiment

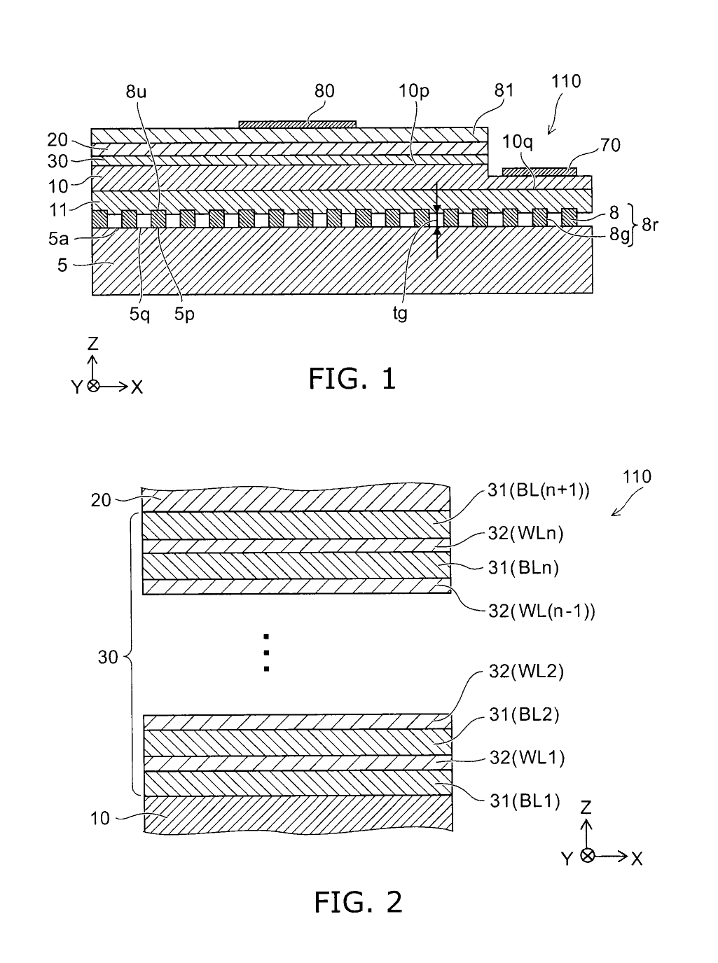

FIG. 1 is a schematic sectional view illustrating the configuration of a semiconductor light emitting device according to a first embodiment.

As shown in FIG. 1, a semiconductor light emitting device 110 includes a silicon substrate 5, a buffer layer 8, a foundation semiconductor layer 11, a first semiconductor layer 10, a light-emitting unit 30, and a second semiconductor layer 20.

The silicon substrate 5 has a major surface 5a. The buffer layer 8 is provided on a part 5p of the major surface 5a of the silicon substrate 5. An example of a planar shape of the buffer layer 8 will be described later.

The foundation semiconductor layer 11 is crystal-grown from an upper surface 8u of the buffer layer 8. The foundation semiconductor layer 11 covers a non-formed region 5q in which the buffer layer 8 is not provided on the major surface 5a. The foundation semiconductor layer 11 is spaced apart from the non-formed region 5q. For example, a gap 8g is provided between the foundation semiconductor layer 11 and the non-formed region 5q.

A space (i.e., the gap 8g) between the major surface 5a of the silicon substrate 5 in the non-formed region 5q and the foundation semiconductor layer 11 is in, for example, a reduced-pressure state (including a vacuum state). The space is filled with air or an inert gas (for example, a nitrogen gas or the like).

The buffer layer 8 has a nano structure. The buffer layer 8 and the gap 8g form a TIR (Total Internal Reflection) mirror 8r.

The first semiconductor layer 10 is provided on the foundation semiconductor layer 11. The first semiconductor layer 10 is of a first conductivity type. The light emitting unit 30 is provided on the first semiconductor layer 10. The second semiconductor layer 20 is provided on the light emitting unit 30. The second semiconductor layer 20 is of a second conductivity type. The second conductivity type is different from the first conductivity type.

For example, the first conductivity type is an n-type, and the second conductivity type is a p-type. The first conductivity type may be the p-type, and the second conductivity type may be the n-type. A case in which the first conductivity type and the second conductivity type are the n-type and the p-type, respectively, will be described below.

In this case, an axis perpendicular to the major surface 5a of the silicon substrate 5 is defined as a Z axis. One axis perpendicular to the Z axis is defined as an X axis. An axis perpendicular to the Z axis and the X axis is defined as a Y axis.

The buffer layer 8 includes, for example, a nitride semiconductor containing aluminum. For example, as the buffer layer 8, for example, an AlN is used.

The foundation semiconductor layer 11, the first semiconductor layer 10, the light emitting unit 30, and the second semiconductor layer 20 include a nitride semiconductor. In the foundation semiconductor layer 11, for example, GaN is used. An impurity concentration in the foundation semiconductor layer 11 is lower than an impurity concentration in the first semiconductor layer 10. In the foundation semiconductor layer 11, for example, GaN to which an impurity is not added is used.

The light emitting unit 30 is provided on a part 10p (a first part) of the first semiconductor layer 10.

The semiconductor light emitting device 110 further includes a first electrode 70, a light transmissive electrode 81, and a second electrode 80. The first electrode 70 is provided on a region 10q (a second part) in which the light emitting unit 30 of the first semiconductor layer 10 is not provided. The light transmissive electrode 81 is provided on the second semiconductor layer 20. The light transmissive electrode 81 is light transmissive to light emitted from the light emitting unit 30. The second electrode 80 is provided on the light transmissive electrode 81. As the light transmissive electrode 81, for example, an ITO (Indium Tin Oxide) or the like is used.

A voltage is applied across the first electrode 70 and the second electrode 80 to supply a current to the light emitting unit 30 through the first semiconductor layer 10 and the second semiconductor layer 20, so that light is emitted from the light emitting unit 30. The semiconductor light emitting device 110 is, for example, an LED (Light Emitting Diode).

FIG. 2 is a schematic sectional view illustrating the configuration of a part of the semiconductor light emitting device according to the first embodiment.

FIG. 2 shows an example of the configuration of the light emitting unit 30.

As shown in FIG. 2, the light emitting unit 30 includes a plurality of barrier layers 31 and a well layer 32 provided between the plurality of barrier layers 31. For example, the plurality of barrier layers 31 and the plurality of well layers 32 are alternately stacked along the Z axis.

In the specification, “stacking” includes not only to stack layers in contact with each other, but also to stack the layers through other layers interposed therebetween. The “to form something on” includes not only to directly form something on, but also to form something on through another layer interposed therebetween.

The well layer 32 includes, for example, Inₓ₁Ga₁₋ₓ₁N (0<x1<1). The barrier layer 31 includes, for example, GaN. More specifically, the well layer 32 includes In, and the barrier layer 31 does not substantially include In. A bandgap energy in the barrier layer 31 is larger than a bandgap energy in the well layer 32.

The light emitting unit 30 may have a single quantum well (SQW: Single Quantum Well) configuration. At this time, the light emitting unit 30 includes the two barrier layers 31 and the well layer 32 provided between the barrier layers 31. Alternatively, the light emitting unit 30 may have a multi-quantum well (MQW) configuration. At this time, the light emitting unit 30 includes the three or more barrier layers 31 and the well layers 32 provided between the barrier layers 31.

More specifically, the light emitting unit 30 includes the (n+1) barrier layers 31 and the n well layers 32 (n is an integer that is 1 or more). An (i+1)th barrier layer BL(i+1) is arranged between an ith barrier layer BLi and the second semiconductor layer 20 (i is an integer that is 1 or more and (n−1) or less). An (i+1)th well layer WL(i+1) is disposed between an ith well layer WLi and the second semiconductor layer 20. A first barrier layer BL1 is provided between the first semiconductor layer 10 and a first well layer WL1. An nth well layer WLn is provided between the nth barrier layer BLn and an (n+1) barrier layer BL(n+1). The (n+1) barrier layer BL(n+1) is provided between the nth well layer WLn and the second semiconductor layer 20.

A peak wavelength of light (emitted light) emitted from the light emitting unit 30 is, for example, 400 nanometers (nm) or more and 650 nm or less. In the embodiment, the peak wavelength is arbitrarily set.

As the first semiconductor layer 10, for example, a GaN layer containing an n-type impurity is used. As the n-type impurity, at least one of Si, Ge, Te, and Sn can be used. The first semiconductor layer 10 includes, for example, an n-side contact layer.

As the second semiconductor layer 20, for example, a GaN layer containing a p-type impurity is used. As the p-type impurity, at least one of Mg, Zn, and C can be used. The second semiconductor layer 20 includes, for example, a p-side contact layer.

Light emitted from the light emitting unit 30 is efficiently reflected by the TIR mirror 8r provided of the buffer layers 8 and the gap 8g. The reflected light travels to the above along a direction from the silicon substrate 5 to the second semiconductor layer 20 and outgoes to the outside of the semiconductor light emitting device 110. In the semiconductor light emitting device 110, the light outgoes from the upper surface of the semiconductor light emitting device 110.

In the semiconductor light emitting device 110, a functional unit including the first semiconductor layer 10, the light emitting unit 30, and the second semiconductor layer 20 is provided on the silicon substrate 5. The silicon substrate 5 has a relatively large area. For this reason, in the semiconductor light emitting device 110, high productivity can be achieved.

In the embodiment, the buffer layer 8 having a nano structure is provided on the major surface 5a of the silicon substrate 5, and the foundation semiconductor layer 11 is provided by lateral growth (ELO: Epitaxial Lateral Overgrowth) from the upper surface 8u of the buffer layer 8. The gap 8g is provided between the non-formed region 5q of the silicon substrate 5 and the foundation semiconductor layer 11 to form the TIR mirror 8r by the buffer layer 8 and the gap 8g. More specifically, a structure (TIR mirror 8r) that reflects light can be provided without increasing the number of processes. In this manner, a semiconductor light emitting device having high productivity and high efficiency can be provided.

In the semiconductor light emitting device using a nitride semiconductor, a semiconductor layer is grown on, for example, an SiC substrate, a sapphire substrate, a silicon substrate, or the like. When the semiconductor light emitting device is to be manufactured, not only productivity but also optical characteristics are important.

The SiC substrate and the sapphire substrate are expensive and have small areas. The SiC substrate and the sapphire substrate are light transmissive to light having a wavelength of 350 nm or more and 500 nm or less. For this reason, when these substrates are used, practical light extraction efficiency can be obtained even though a simple structure such as a face-up structure or a flip-chip structure is employed.

On the other hand, the silicon substrate has quality higher than and an area larger than those of the SiC substrate and the sapphire substrate. However, the silicon substrate strongly absorbs light in a visible waveband. For this reason, when a semiconductor layer is crystal-grown by using a silicon substrate, a method of bonding the crystal-grown semiconductor layer to another support substrate to remove a silicon growing substrate is employed.

The semiconductor layer is bonded to the support substrate by heating or the like. The heating may adversely affect a metal of an electrode or the like. Light emitting characteristics may be deteriorated by a change in stress balance caused by thermal expansion. The growing substrate is removed by polishing and etching or peeling performed by a laser lift-off procedure. The former has low process efficiency. The latter causes a decrease in yield due to thermal shock. In both the cases, light emitting characteristics may be deteriorated by the release of residual stress generated in crystal growth. Thus, a method that does not require substrates to be re-covered is demanded.

When a silicon substrate to be crystal-grown is directly used, light traveling into the silicon substrate is absorbed to cause a loss. For example, a method of forming a metal mesh mirror on the silicon substrate to selectively grow a nitride semiconductor from a portion that is not covered with the mesh mirror on the silicon substrate is conceived. However, a growth temperature of the nitride semiconductor is a high temperature, i.e., 1000° C. or higher. Since a metal that is chemically stable at this temperature has a low reflectance, the method is not practical.

In the embodiment, the buffer layer 8 is formed on the silicon substrate 5 for crystal growth. The buffer layer 8 has, for example, a columnar shape or a wall-like shape. These shapes are formed by, for example, a method such as patterning. More specifically, the buffer layer 8 having a nano structure is provided. A layer serving as a light emitting element is selectively grown on the buffer layer 8. In this manner, between the growing substrate and the layer serving as a light emitting element, a reflecting structure (TRI mirror 8r) is formed from the buffer layer 8 and the gap 8g (for example, an air layer). A portion serving as a light emitting element is formed on the substrate for crystal growth, a part or a whole of the substrate for crystal growth is left to form a support substrate. In this manner, the silicon substrate 5 is used as the substrate for crystal growth, and re-covering of substrates can be made unnecessary. In this manner, light can be practically extracted at high productivity.

The buffer layer 8 is almost light transmissive to a light-emitting wavelength. A refractive index of the buffer layer 8 is lower than a refractive index of the foundation semiconductor layer 11. In the buffer layer 8, a void (gap 8g) having a nano structure is provided.

A combination of the buffer layer 8 and the gap 8g serves as the TIR mirror 8r. The TIR mirror 8r is designed to narrow an escape cone with respect to light traveling from the semiconductor layer to the silicon substrate 5. At an average of all solid angles, a reflectance that is substantially equal to that of a metal mirror can be obtained.

An upper surface of the void in the buffer layer 8 (a lower surface of a portion facing the non-formed region of the foundation semiconductor layer) is lower than a position of a lower surface of the first electrode 70. In this manner, sufficient current diffusion can be obtained.

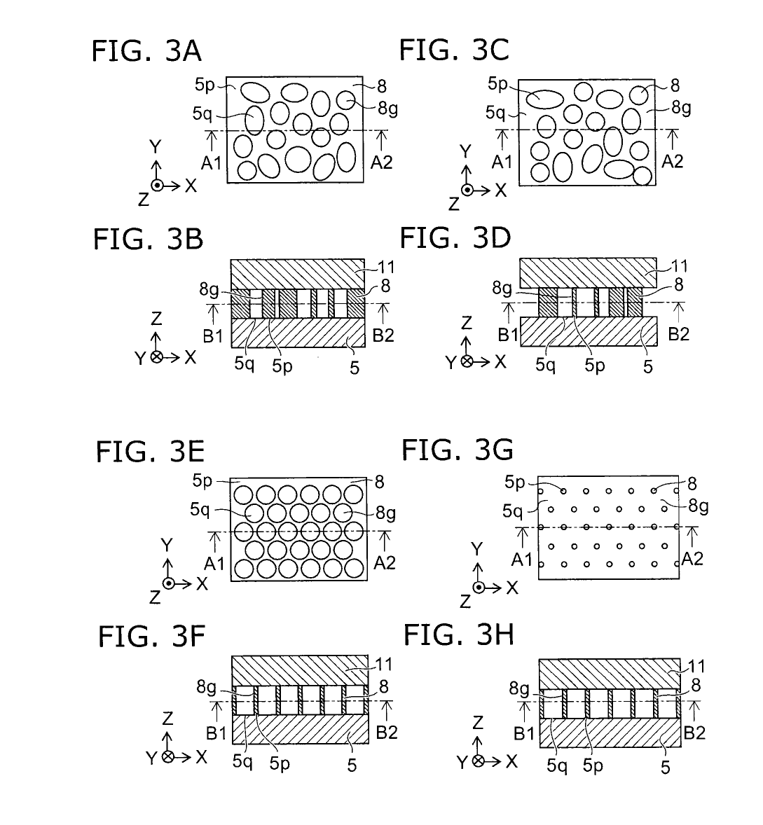

FIG. 3A to FIG. 3H are schematic sectional views illustrating the configuration of a part of the semiconductor light-emitting device according to the first embodiment.

FIG. 3A, FIG. 3C, FIG. 3E, and FIG. 3G show sections along B1 to B2 lines in FIG. 3B, FIG. 3D, FIG. 3F, and FIG. 3H, respectively. FIG. 3B, FIG. 3D, FIG. 3F, and FIG. 3H show sections along A1 to A2 lines in FIG. 3A, FIG. 3C, FIG. 3E, and FIG. 3G, respectively.

In the example shown in FIG. 3A and FIG. 3B, the buffer layer 8 is continuous. More specifically, the part 5p of the major surface 5a of the silicon substrate 5 on which the buffer layer 8 is provided is continuous. The non-formed region 5q is provided in a plurality, the plurality of the non-formed regions have an island-like shape. The gap 8g has an island-like shape. In the example, the void (gap 8g) is columnar.

In the example shown in FIG. 3C and FIG. 3D, the gap 8g is continuous, the non-formed region 5q is continuous. The buffer layer 8 is provided in a plurality, the plurality of buffer layers 8 have an island-like shape. The part 5p of the major surface 5a of the silicon substrate 5 has an island-like shape. In the example, the void (gap 8g) has a wall-like shape.

In the examples shown in FIG. 3A and FIG. 3B and FIG. 3C and FIG. 3D, the shape and the arrangement of the buffer layer 8 or the gap 8g are irregular.

In the example shown in FIG. 3E and FIG. 3F, the buffer layer 8 (and the part 5p) is continuous. The non-formed region 5q has an island-like shape, and the gap 8g has an island-like shape.

In the example shown in FIG. 3G and FIG. 3H, the gap 8g is continuous, the non-formed region 5q is continuous, and the buffer layer 8 (and the part 5p) have island-like shapes.

In the examples shown in FIG. 3A and FIG. 3B and FIG. 3C and FIG. 3D, the shape and the arrangement of the buffer layer 8 or the gap 8g are regular. In these examples, the buffer layer 8 and the gap 8g are arrayed in the form of a lattice.

The above configuration is an example of the configuration of the buffer layer 8 (and the gap 8g). Furthermore, the configuration may have a shape or an arrangement such as a fingerprint-like shape or a nervure-like shape.

An area ratio of a nano-structure void (gap 8g) in the plane is, for example, 50% or more and 95% or less. More specifically, the area ratio of the gap 8g is higher than an area ratio of the buffer layer 8. In other words, a ratio of the sectional area of the buffer layer 8 obtained by cutting the buffer layer 8 along a plane parallel to the major surface 5a to the area of the major surface 5a exceeds 5% and is less than 50%.

When a photonic band effect cannot be obtained, a reflectance becomes high when the area ratio of the void (gap 8g) in the plane is high. When the area ratio is excessively high, a thermal conductivity decreases, and device characteristics are deteriorated. When the area ratio of the void (gap 8g) in the plane is excessively high, mechanical strength easily lowers.

For example, when the buffer layer 8 is an AlN in a GaN-based blue LED, a light extraction efficiency of 50% or more can be obtained when a ratio of an area occupied by the void is 50% or more. When the ratio of the area occupied by the void is 90% or less, a thermal conductivity that is equal to or higher than that of Si₃N₄ can be obtained. When the ratio of the occupied area of the void is 95% or less, a thermal conductivity that is almost equal to or higher than that of SiO₂ of crystal can be obtained. A range of the actual ratio of the area occupied by the void determined in consideration of heat dissipation is 50% or more and 95% or less.

The size of the void (gap 8g) is almost equal to the thickness of the foundation semiconductor layer 11. If the size is larger than the thickness, thermal diffusion is deteriorated in uniformity, and device characteristics may be adversely affected. The size of the void (gap 8g) is preferably equal to or larger than a size in which a photonic band is formed as a periodical structure. According to the effect, the reflectance can be increased. In this case, the size of the void (gap 8g) is ½ or less and ⅓ or more an emission wavelength. A condition in which a transmittance increases due to the photonic band effect is also present. However, in the embodiment, the condition causes a deterioration of performance.

The “wavelength” in the specification means a wavelength which light emitted from a light emitting unit exhibits in the mentioned member.

A thickness tg (length along the Z axis, see FIG. 1) of the void (gap 8g) is preferably ⅓ or more a peak wavelength of the light. More specifically, a distance between the major surface 5a of the silicon substrate 5 in the non-formed region 5q and the foundation semiconductor layer 11 is preferably ⅓ or more a peak wavelength of light emitted from the light-emitting unit 30. When the distance is smaller than ⅓ of the peak wavelength, the effect of total reflection is reduced, and tunneling to the silicon substrate 5 caused by evanescent wave coupling becomes conspicuous.

As the thickness tg of the void (gap 8g), several appropriate values are present. This is caused by an augmentation effect of reflection by interference between reflected light from a Si surface in the void and light reflected by a semiconductor layer. The appropriate value changes depending on methods of arranging voids and ratios of occupied areas

The thickness tg of the void (gap 8g) is 1 micrometer (μm) or less. In this manner, a predetermined thermal conductivity is obtained, and high quality crystal growth can be obtained.

In the gap 8g, for example, a vacuum state is set. The gap 8g may be filled with air, an inert gas, or the like. At least a part of the gap 8g may be filled with liquid or solid having a low dielectric constant. A refractive index of the liquid or the solid with which the gap 8g is filled is lower than a refractive index of the buffer layer 8. A refractive index of the liquid or the solid is lower than a refractive index of the foundation semiconductor layer 11. The refractive index of the liquid or the solid is, for example, 1.5 or less.

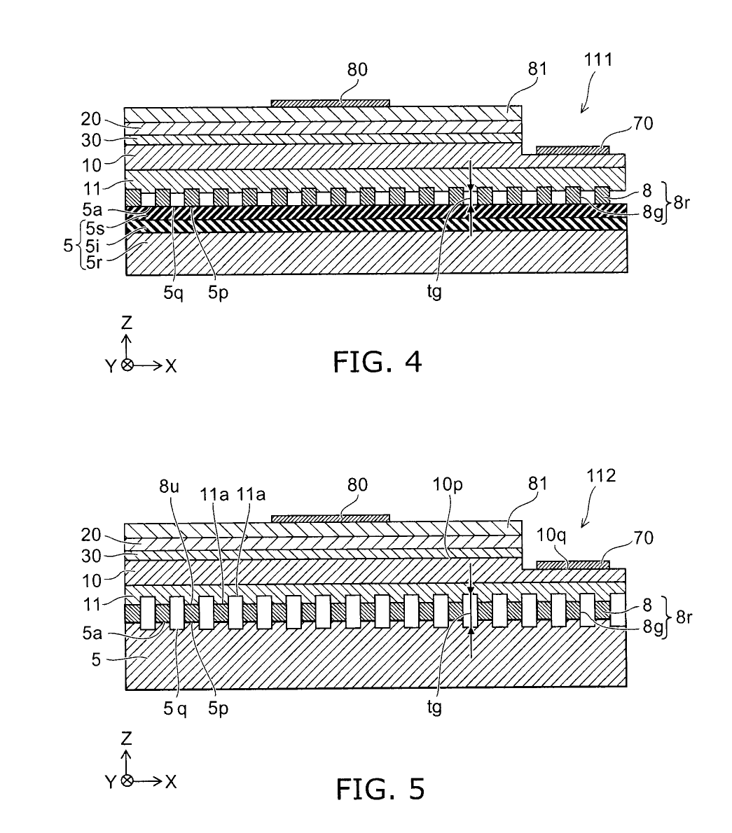

FIG. 4 is a schematic sectional view illustrating the configuration of another semiconductor light emitting device according to a first embodiment.

As shown in FIG. 4, in another semiconductor light emitting device 111 according to the embodiment, the silicon substrate 5 includes a base substance 5r, an insulating layer 5i provided on the base substance 5r, and a silicon layer 5s provided on the insulating layer 5i. More specifically, as the silicon substrate 5, an SOI (Silicon On Insulator) is used. The other configurations are the same as those in the semiconductor light emitting device 110.

Also when the silicon substrate 5 having an SOI structure is used, the buffer layer 8 is formed on the major surface 5a of the silicon substrate 5, and the foundation semiconductor layer 11 is formed by ELO. In this manner, the TIR mirror 8r is formed by the buffer layer 8 and the gap 8g. In this manner, a semiconductor light emitting device having high productivity and high efficiency can be provided.

FIG. 5 is a schematic sectional view illustrating the configuration of another semiconductor light emitting device according to the first embodiment.

As shown in FIG. 5, in another semiconductor light emitting device 112 according to the embodiment, the non-formed region 5q of the major surface 5a of the silicon substrate 5 is recessed from the part 5p in which the buffer layer 8 on the major surface 5a is provided. Furthermore, a lower surface 11a of the foundation semiconductor layer 11 facing the non-formed region 5q is recessed from a lower surface 11b of the foundation semiconductor layer 11 facing the buffer layer 8. The lower surface 11a is located above the lower surface 11b. More specifically, the gap 8g (void) provided in the buffer layer 8 includes the recessed portion of the silicon substrate 5 and the recessed portion of foundation semiconductor layer 11. The other configurations are the same as those in the semiconductor light emitting device 110.

Also in the semiconductor light emitting device 112, the TIR mirror 8r is formed from the buffer layer 8 and the gap 8g. In this manner, a semiconductor light emitting device having high productivity and high efficiency can be provided.

An example of characteristics of a semiconductor light emitting device according to the embodiment will be described below.

A case in which AlN is used as the buffer layer 8 and GaN is used as the foundation semiconductor layer 11, the first semiconductor layer 10, and the second semiconductor layer 20 will be described below.

A wavelength of light emitted from the light emitting unit 30 is set to 450 nm. With respect to the light, reflection characteristics on interfaces of GaN/AlN/Si are calculated. A refractive index of GaN is 2.47, and a refractive index of AlN is 2.11. As a distribution of light emission, a dipole light-emission distribution (isotropic luminous intensity distribution) and a Lambert luminous intensity distribution are assumed. When light emitted from the light emitting unit 30 is directly incident on the interface, an isotropic luminous intensity distribution is obtained. When light diffusely reflected in the semiconductor layer is incident on the interface, a Lambert luminous intensity distribution is obtained. In order to accurately calculate light extraction efficiency, the two reflection characteristics are calculated.

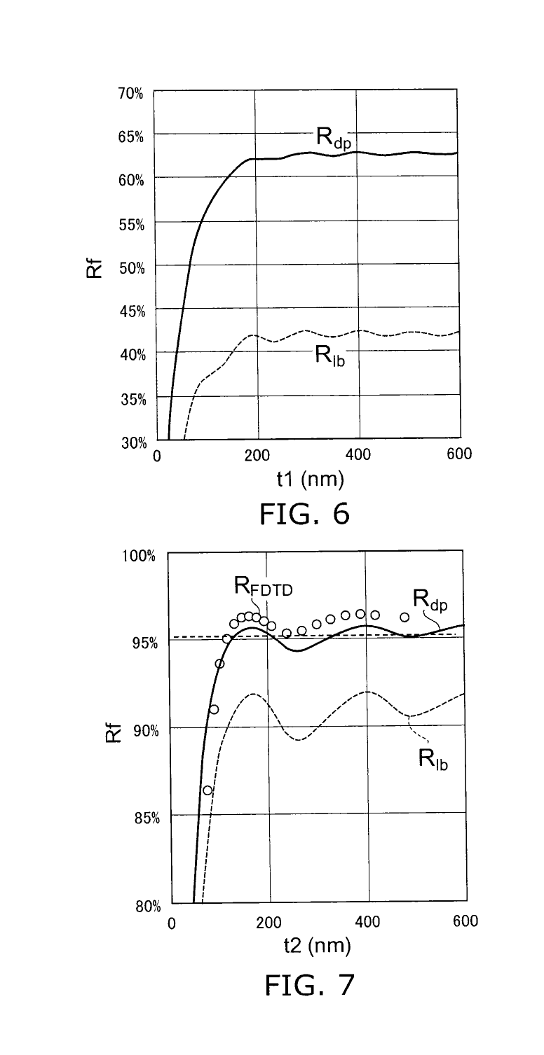

FIG. 6 is a graph illustrating characteristics of the semiconductor light emitting device according to the first embodiment.

FIG. 6 shows an average reflectance of all solid angles when the thickness of the AlN layer is changed. The abscissa indicates a thickness t1 (nm) of the AlN film, and the ordinate indicates an average reflectance Rf (%). FIG. 6 shows an average reflectance R_{dp} about a dipole light emission distribution (isotropic luminous intensity distribution) and an average reflectance R_{lb} about a Lambert luminous intensity distribution.

The average reflectance R_{dp} about the isotropic luminous intensity distribution is relatively high. In contrast to this, the average reflectance R_{lb} about the Lambert luminous intensity distribution is low. This is because, in the Lambert luminous intensity distribution, a ratio of a vertical incidence component is high, and a ratio of a total reflection becomes relatively low. The average reflectance R_{dp} and the average reflectance R_{lb} sharply lower when the thickness t1 is 200 nm or less. This is because tunneling is mainly caused by an evanescent wave.

FIG. 7 is a graph illustrating characteristics of the semiconductor light-emitting device according to the first embodiment.

FIG. 7 shows characteristics obtained when the buffer layer 8 is replaced with air. The abscissa indicates a thickness t2 (nm) of an air layer, and the ordinate indicates an average reflectance Rf (%). FIG. 7 shows, in addition to the average reflectance R_{dp} about the isotropic luminous intensity distribution and the average reflectance R_{lb} about the Lambert luminous intensity distribution, an average reflectance R_{FDTD} calculated by an FDTD (Finite Difference Time Domain) method. In the average reflectance R_{FDTD}, a configuration in which a columnar AlN is disposed in the form of photonic crystal is supposed.

As is apparent from FIG. 7, when the thickness t2 of the air layer is 200 nm or more, the average reflectance R_{dp} about the isotropic luminous intensity distribution is about 95%, and the average reflectance R_{lb} about the Lambert luminous intensity distribution is 90% or more. The average reflectance R_{FDTD} exhibits a value approximate to the average reflectance R_{dp}. The high reflectance is obtained as described above because a difference between the refractive indexes of air and GaN and a difference between the refractive indexes of air and Si are large. On an interface between metal aluminum and GaN, the average reflectance R_{dp} is 87%, and the average reflectance R_{lb} is 85%. When the air layer is provided, a reflectance exceeding these values can be obtained. The thickness t2 at which the high average reflectance Rf is obtained by an interference effect is discrete. When the thickness t2 falls within the range of 130 nm or more to 200 nm or less or the range of 350 nm or more to 430 nm or less, a high average reflectance Rf can be obtained.

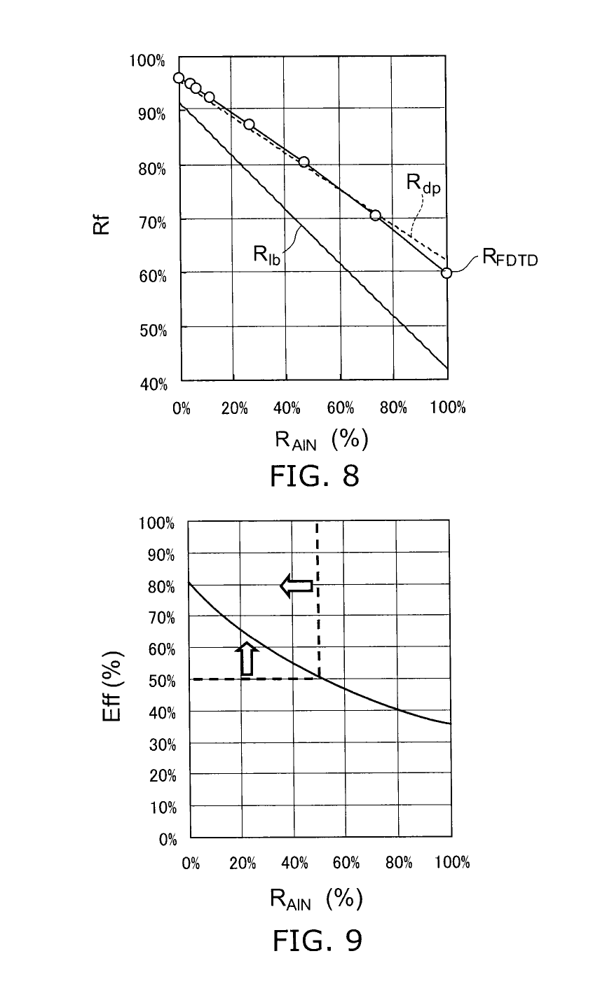

FIG. 8 is a graph illustrating characteristics of the semiconductor light emitting device according to the first embodiment.

FIG. 8 illustrates characteristics obtained when a ratio of the areas of the AlN layer and the air layer is changed. In the example, the characteristics of AlN and the characteristics of air are linearly averaged. The abscissa in FIG. 8 indicates an area ratio R_{AlN} (%) to the entire area of the AlN layer. A state in which the area ratio R_{AlN} is 100% corresponds to a state in which the entire surface is covered with the AlN layer. A state in which the area ratio R_{AlN} is 0% corresponds to a state in which the entire surface is covered with air. The ordinate indicates the average reflectance Rf. In this example, the thickness of the AlN layer is 200 nm.

As is apparent from FIG. 8, the average reflectance R_{FDTD} is very exactly equal to a value of a linear average of average reflectance R_{dp}. This means that a photonic band effect cannot be obtained. This case means that a reflectance is determined by the area ratio R_{AlN} (%) (or a ratio of area occupied by a void) of the AlN layer.

On the basis of the above result, a light extraction efficiency Eff (limiting efficiency) in the semiconductor light emitting device can be calculated. The light extraction efficiency Eff is approximately expressed as follows.

Eff={(1+R_{dp})/2}·(1−Rₑₓₜ)/(1−r·R_{lb}·Rₑₓₜ)

where, R_{dp} is a reflectance of the TIR mirror 8r in an isotropic luminous intensity distribution, R_{lb} is a reflectance of the TIR mirror 8r in a Lambert luminous intensity distribution, Rₑₓₜ is a reflectance of a light extracting surface, and r is an internal damping.

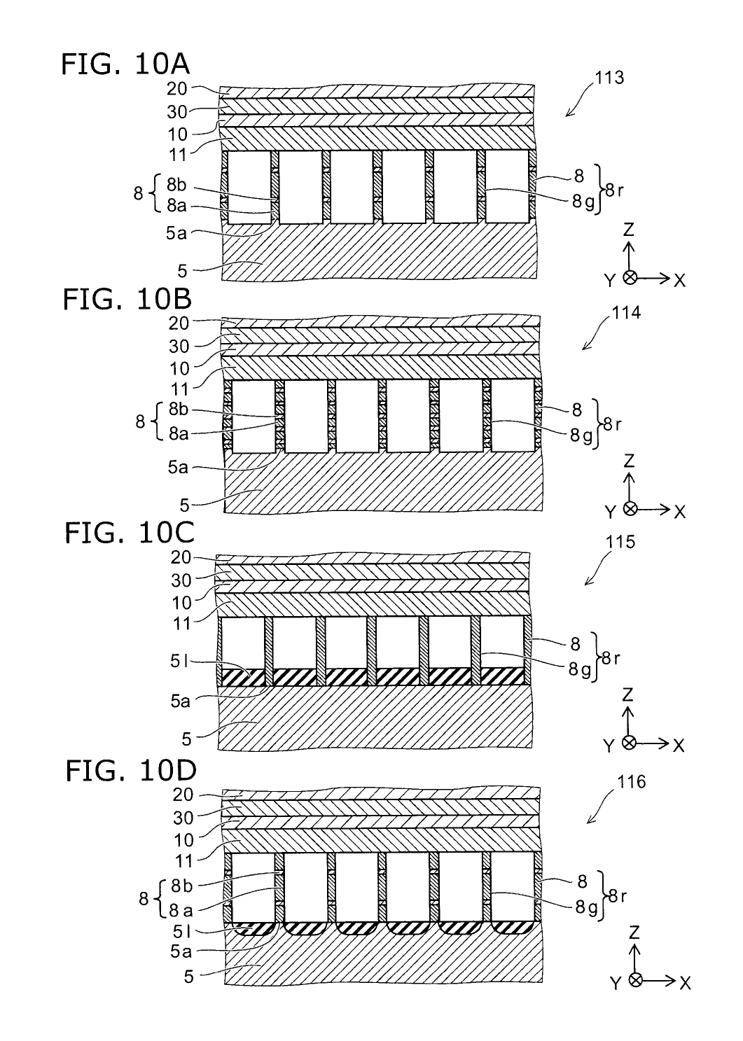

FIG. 9 is a graph illustrating characteristics of the semiconductor light emitting device according to the first embodiment.

The abscissa in FIG. 9 indicates an area ratio R_{AlN} (%) to the entire area of the AlN layer, and the ordinate indicates the light extraction efficiency Eff.

As shown in FIG. 9, when the area ratio R_{AlN} (%) to the entire area of the AlN layer is 50% or less (ratio of an area occupied by a void is less than 50%), a light extraction efficiency Eff of 50% or more can be obtained. In this manner, in the semiconductor light emitting device 110, a ratio of the sectional area of the buffer layer 8 obtained by cutting the buffer layer 8 along a plane parallel to the major surface 5a to the area of the major surface 5a is less than 50%. In this manner, the light extraction efficiency Eff is higher than 50%. When a ratio of the sectional area of the buffer layer 8 to the area of the major surface 5a is smaller than 5%, as described above, a thermal conductivity and a mechanical strength decrease. When a ratio of an area occupied by a void is increased, a light extraction efficiency Eff of 80% can be theoretically obtained.

FIG. 10A to FIG. 10D are schematic sectional views illustrating the configuration of still another semiconductor light emitting device according to the first embodiment.

As shown in FIG. 10A and FIG. 10B, in semiconductor light emitting devices 113 and 114 according to the embodiment, the buffer layer 8 includes a plurality of first layers 8a and a second layer 8b. The second layer 8b is provided between the plurality of first layers 8a. A refractive index of the second layer 8b is different from a refractive index of the first layers 8a. The first layer 8a is, for example, an AlN layer. The second layer 8b is, for example, an AlGaN layer or a GaN layer. A composition ratio of Al in the second layer 8b is lower than a composition ratio of Al in the first layer 8a. The other configurations are the same as those in, for example, the semiconductor light emitting device 110.

In the semiconductor light emitting device 113, a thickness of the first layer 8a is, for example, 10 nm or more and 50 nm or less, and a thickness of the second layer 8b is 200 nm or more and 300 nm or less. In the semiconductor light emitting device 114, the thickness of first layer 8a is, for example, 30 nm or more and 80 nm or less, and the thickness of second layer 8b is 30 nm or more and 80 nm or less.

The first layer 8a and the second layer 8b, for example, form a DBR reflecting structure. In this manner, a higher reflectance can be obtained.

As shown in FIG. 10C, in a semiconductor light emitting device 115, a low refractive index layer 5l is provided on at least a part of a space between the major surface 5a of the silicon substrate 5 in the non-formed region 5q and the foundation semiconductor layer 11. The low refractive index layer 5l is made of liquid or solid. In this manner, at least a part of the gap 8g (void) is filled with liquid or solid.

As the low refractive index layer 5l, for example, SiO₂ is used. The low refractive index layer 5l is provided on the major surface 5a of the silicon substrate 5 to be in contact with the major surface 5a. The low refractive index layer 5l can be formed by, for example, oxidizing a surface of the silicon substrate 5 in the non-formed region 5q. The low refractive index layer 5l is provided to make it possible to further improve the reflectance.

As shown in FIG. 10D, in a semiconductor light emitting device 116, as the buffer layer 8, the plurality of first layers 8a and the second layer 8b are provided, and the low refractive index layer 5l is additionally provided. In this manner, the reflectance can be further increased.

### Second Embodiment

A second embodiment is related to a method for manufacturing a semiconductor light emitting device.

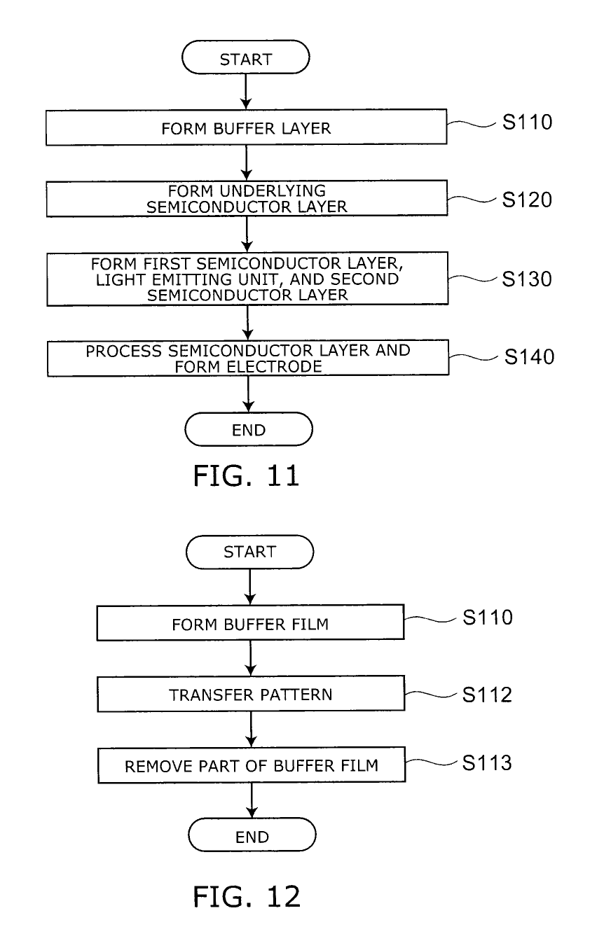

FIG. 11 is a flow chart illustrating a method for manufacturing a semiconductor light emitting device according to the second embodiment.

In the manufacturing method, the buffer layer 8 is formed on a part of the major surface 5a of the silicon substrate 5 (step S110). The foundation semiconductor layer 11 spaced apart from the non-formed region 5q is laterally crystal-grown from the upper surface of the buffer layer 8 to cover the non-formed region 5q in which the buffer layer 8 is not provided on the major surface 5a (step S120). The first semiconductor layer 10 of a first conductivity type is crystal-grown on the foundation semiconductor layer 11, the light emitting unit 30 is crystal-grown on the first semiconductor layer 10, and the second semiconductor layer 20 of a second conductivity type is crystal-grown on the light emitting unit 30 (step S130). Furthermore, the semiconductor layers (the first semiconductor layer 10, the light emitting unit 30, and the second semiconductor layer 20) are processed into predetermined shapes to form electrodes (the first electrode 70, the second electrode 80, the light transmissive electrode 81, and the like) (step S140).

In the manufacturing method, step S110 corresponds to the process of manufacturing a gallium nitride crystal growth substrate for light emitting device. The gallium nitride crystal growth substrate for light emitting device includes the silicon substrate 5 and a high-reflectance void layer formed on the silicon substrate 5. Step S120 to step S140 correspond to processes of manufacturing a face-up type LED element unit. Step S120 corresponds to formation of a semiconductor layer by ELO growth, step S130 corresponds to formation of a semiconductor functional layer, and step S140 corresponds to device formation.

FIG. 12 is a flow chart illustrating a part of a method for manufacturing a semiconductor light emitting device according to the second embodiment.

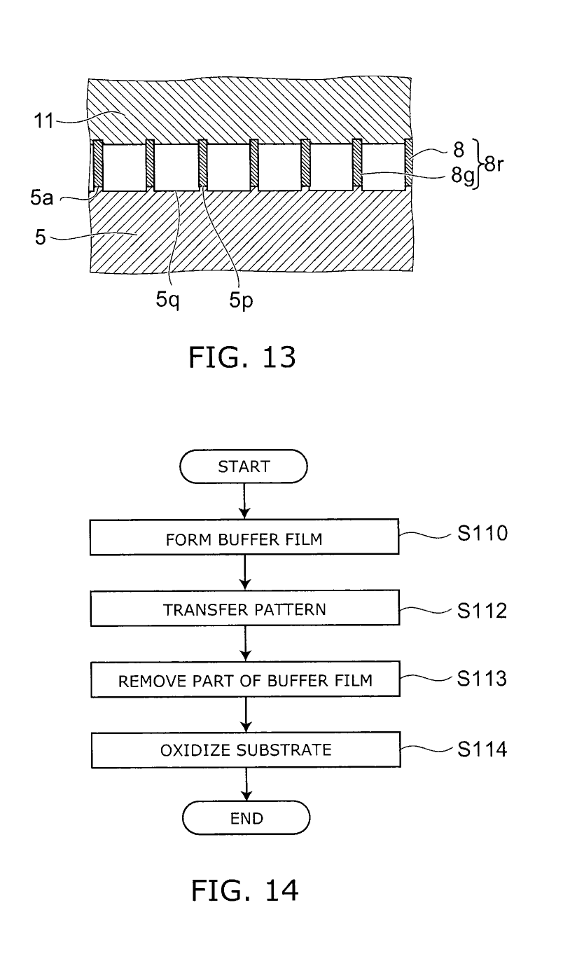

FIG. 13 is a schematic sectional view illustrating a part of the semiconductor light emitting device according to the second embodiment.

FIG. 12 shows one example of step S110. As shown in FIG. 12, for example, a buffer film serving as the buffer layer 8 is formed on the silicon substrate 5 (step S111), a pattern layer to which a predetermined pattern is transferred is formed on the buffer layer (step S112), and the buffer film is partially removed by using the pattern layer as a mask (step S113). In this manner, the buffer layer 8 is formed.

For example, a semiconductor layer serving as a buffer film and including an AlN film and an i-GaN film is crystal-grown on the major surface 5a of the silicon substrate 5. The crystal-grown layer has a thickness of 100 nm or more, and, more preferably, 200 nm or more.

A mask film is formed on the crystal-grown semiconductor layer, and the mask film is processed in a predetermined shape to form a mask layer. Thereafter, the semiconductor layer is partially removed by using the mask layer as a mask. In this manner, the TIR mirror 8r is formed. The mask film is processed by using, for example, nano printing, interference exposure, electron beam exposure, ion beam exposure, or the like. In this manner, a nanometer-order periodic structure can be obtained. On the TIR mirror 8r, a reflectance can be increased by a photonic band effect. A depth of a removed portion is ⅓ or more the wavelength, for example, 200 nm or more. A hole that penetrates the semiconductor layer is formed by removal to preferably expose the silicon substrate 5. Furthermore, the hole may reach the inside of the silicon substrate 5. In this manner, the thickness of the void can be increased.

Thereafter, as shown in FIG. 13, by using the substrate on which the buffer layer 8 is formed, a semiconductor crystal (foundation semiconductor layer 11) is grown. In an initial stage of crystal growth, a crystal growth mode by ELO is used. In this manner, the foundation semiconductor layer 11 covers the non-formed region 5q in which the buffer layer 8 is not provided on the major surface 5a and is spaced apart from the non-formed region 5q. The void (gap 8g) is formed, and the TIR mirror 8r is formed. Thereafter, furthermore, a semiconductor functional layer is formed, and device processing is performed.

FIG. 14 is a flow chart illustrating a method for manufacturing a semiconductor light emitting device according to the second embodiment.

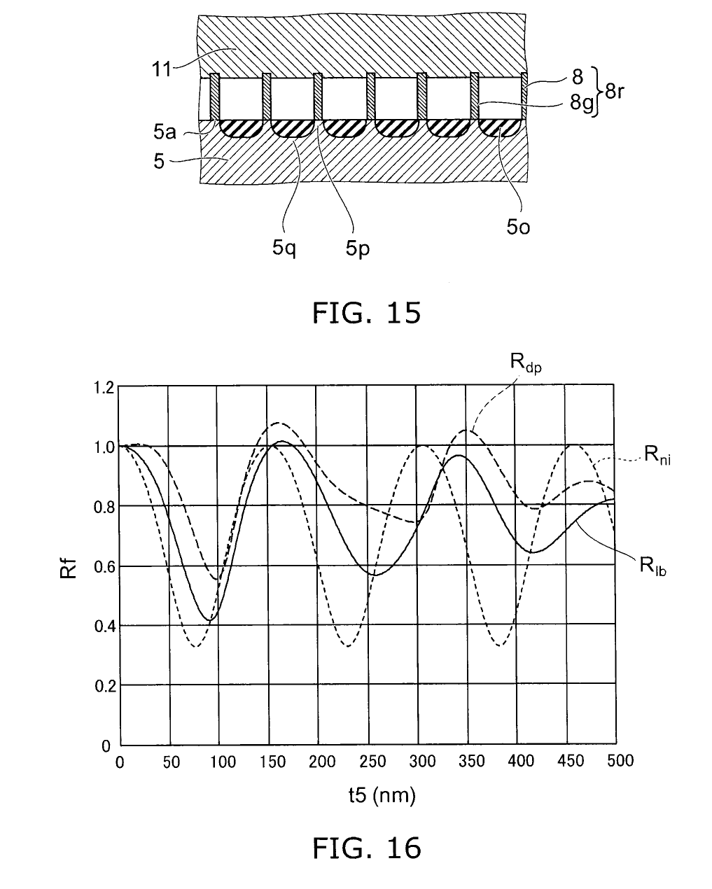

FIG. 15 is a schematic sectional view illustrating a part of the semiconductor light emitting device according to the second embodiment.

As shown in FIG. 14 and FIG. 15, after the buffer layer 8 is formed in step S113, the surface of the silicon substrate 5 that is not covered with the buffer layer 8 is oxidized (step S114). As the oxidation, thermal oxidation is used. In this manner, in the non-formed region 5q of the major surface 5a of the silicon substrate 5, an SiO₂ film 5o different from air is formed. The SiO₂ film 5o is a low dielectric constant layer.

When the SiO₂ film 5o is formed to reduce a contact area between the buffer layer 8 and the silicon substrate 5, a reflectance is improved. Furthermore, for example, the reflectance is improved by the TIR of a three-layer structure of air/SiO₂ film 5o/Si.

FIG. 16 is a graph illustrating characteristics of the semiconductor light emitting device according to the second embodiment.

FIG. 16 shows a relationship between a thickness and a reflectance of the SiO₂ film 5o. The abscissa indicates a thickness t3 (nm) of the SiO₂ film 5o. The ordinate indicates a standardized reflectance Rr that is defined as 1 when the thickness t3 of the SiO₂ film 5o is 0. This drawing shows, in addition to the average reflectance R_{dp} and the average reflectance R_{lb}, a reflectance Rₙᵢ about vertical incidence. This example shows characteristics for light having a wavelength of 450 nm.

As is apparent from FIG. 16, when the thickness t3 of the SiO₂ film 5o is 30 nm or less or 150 nm or more and 180 nm or less, the average reflectance R_{dp}, the average reflectance R_{lb}, and the reflectance Rₙᵢ increase. For this reason, in a light emitting device having an emission wavelength of 450 nm, the thickness of the SiO₂ film 5o is preferably 30 nm or less or 150 nm or more and 180 nm or less.

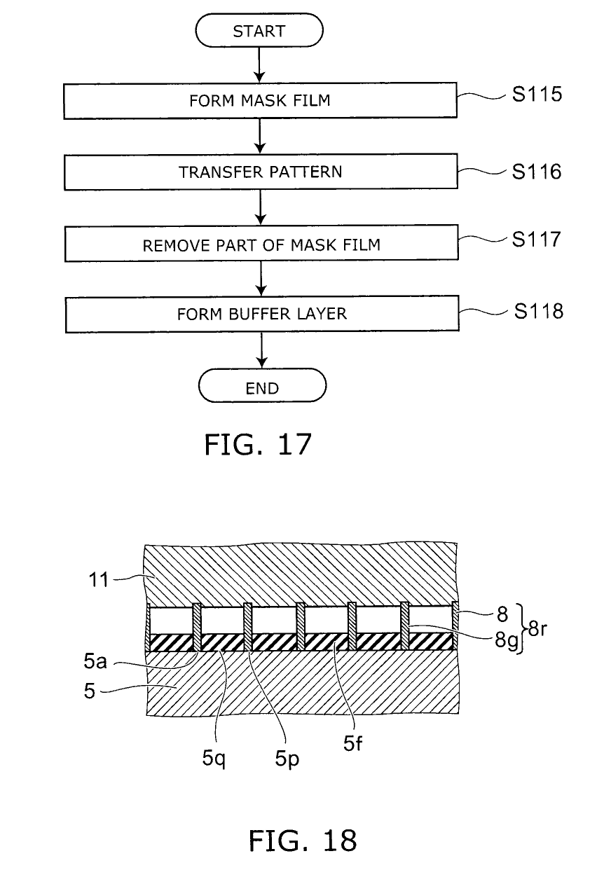

FIG. 17 is a flow chart illustrating a part of the method of manufacturing a semiconductor light emitting device according to the second embodiment.

FIG. 18 is a schematic sectional view illustrating a part of the semiconductor light emitting device according to the second embodiment.

As shown in FIG. 17 and FIG. 18, a mask film 5f is formed on the major surface 5a of the silicon substrate 5 (step S115). As the mask film 5f, for example, a dielectric layer is used. As the mask film 5f, for example, a Si oxide film, a Si nitride film, a Si carbide film, or the like can be used. These films can be formed by, for example, sputtering, deposition, CVD, or the like. The surface of the silicon substrate 5 may be caused to react to form the mask film 5f. The mask film 5f is light transmissive and has a low refractive index. As the mask film 5f, a material that can withstand a high temperature of about 1200° C. is used.

For example, in a light emitting device having an emission wavelength of 450 nm, the thickness of the mask film 5f is preferably 30 nm or less or 150 nm or more and 180 nm or less. In this manner, a high reflectance can be obtained.

A pattern layer to which a predetermined pattern is transferred is formed on the mask film 5f (step S116), and the mask film is partially removed by using the pattern layer as a mask (step S117). In this manner, a mask film 5f to which the pattern is transferred can be formed. Thereafter, the buffer layer 8 (for example, an AlN film) is formed on the surface of the processed body (step S118). The AlN film serving as the buffer layer 8 is formed on a portion except for a residual portion of the mask film 5f (i.e., on the silicon substrate 5).

Thereafter, a semiconductor crystal (foundation semiconductor layer 11) is grown. In an initial stage of the crystal growth, by using a crystal growing mode of ELO, a void (gap 8g) is formed between the foundation semiconductor layer and the silicon substrate 5 (between the foundation semiconductor layer 11 and the mask film 5f). In this manner, the TIR mirror 8r is formed. Thereafter, furthermore, a semiconductor functional layer is formed, and device processing is performed.

### Third Embodiment

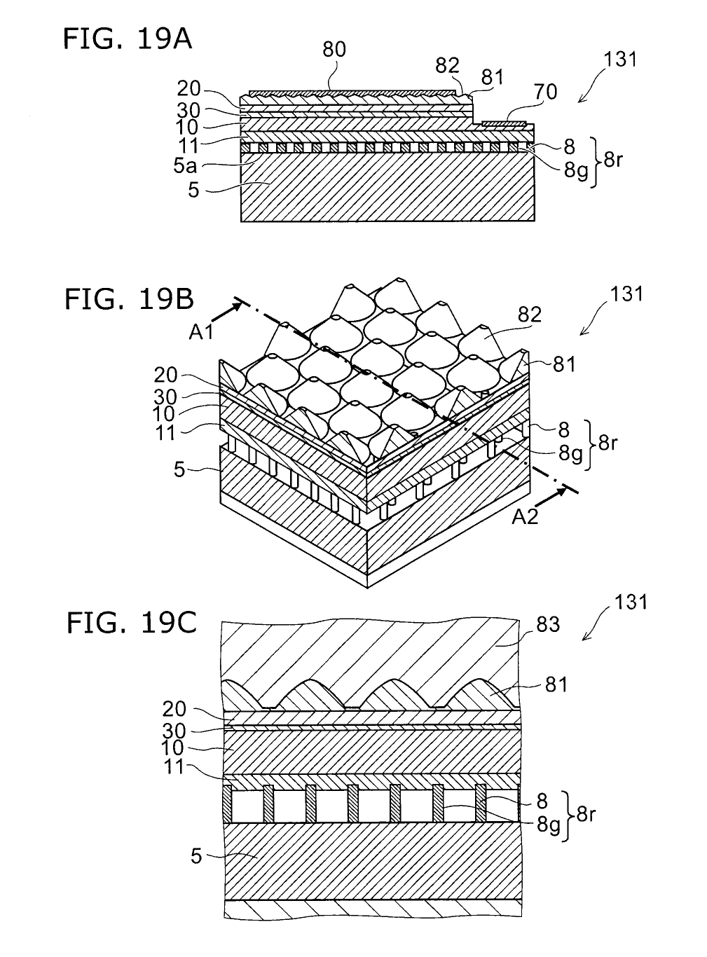

FIG. 19A to FIG. 19C are schematic views illustrating the configuration of a semiconductor light emitting device according to a third embodiment.

FIG. 19A is a schematic sectional view, FIG. 19B is a schematic perspective view showing an enlarged part, and FIG. 19C is a sectional view along an A1 to A2 line in FIG. 19B.

As shown in FIG. 19A to FIG. 19C, in a semiconductor light emitting device 131 according to the embodiment, an unevenness 82 is provided on an upper surface of the light transmissive electrode 81. As the other configurations, the configurations in arbitrary one of semiconductor light emitting devices according to the first to third embodiments can be used.

In the semiconductor light emitting devices according to the first to fourth embodiments, light is extracted from an upper surface (surface opposite of the silicon substrate 5). For this reason, a configuration different from that in a sapphire-substrate-based light emitting device is employed. More specifically, a configuration to cause an upper surface to emit a larger amount of light is employed. The unevenness 82 of the light transmissive electrode 81 has, for example, a texture pattern. In this manner, light extraction efficiency is improved.

A vertical interval of the unevenness 82 is preferably ½ or more a peak wavelength of light emitted from the light emitting unit 30. The vertical interval is preferably the peak wavelength or more. When the second semiconductor layer 20 is thin, or when a light absorption of the light transmissive electrode 81 is relatively high, in consideration of current diffusion or light absorption, the vertical interval of the unevenness 82 is set to ½ or more of the peak wavelength and the peak wavelength or less.

As shown in FIG. 19C, a seal layer 83 having a low refractive index may be provided on the light transmissive electrode 81.

An inclined portion or an unevenness may be formed on at least one of a step portion between the first semiconductor layer 10 and the second semiconductor layer between the first electrode 70 and the second electrode 80 and a side surface of the chip.

### Fourth Embodiment

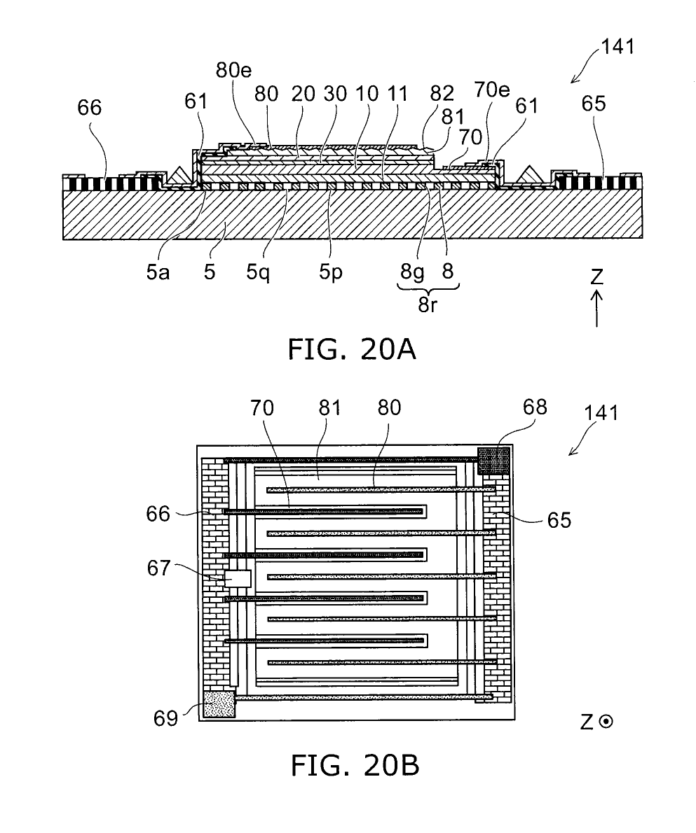

FIG. 20A and FIG. 20B are schematic views illustrating the configuration of a semiconductor light emitting device according to a fourth embodiment.

As shown in FIG. 20A and FIG. 20B, a semiconductor light emitting device 141 according to the embodiment includes an electronic circuit formed on the silicon substrate 5. In the example, as the electronic circuit, a first electronic circuit 65, a second electronic circuit 66, a silicon photosensor 67, or the like are provided. At least a part of the electronic circuit is electrically connected to at least one of the first semiconductor layer 10 and the second semiconductor layer 20.

In this example, the first electronic circuit 65 is electrically connected to the first electrode 70. The second electronic circuit 66 is electrically connected to the second electrode 80. An insulating layer 61 is provided between an interconnection 70e that connects the first electronic circuit 65 and the first electrode 70 to each other and the silicon substrate 5. The insulating layer 61 is provided between an interconnection 80e that connects the second electronic circuit 66 and the second electrode 80 to each other and the silicon substrate 5.

The electronic circuit can have a function of controlling a current flowing in the light emitting unit 30. The electronic circuit may have another function.

In the semiconductor light emitting device 141, as the electronic circuit, the silicon photosensor 67 is provided. On the basis of a detection result of light by the silicon photosensor 67, the current flowing in the light emitting unit 30 may be controlled. A GND terminal 69 and a Vcc terminal 68 are provided. The terminals are connected to a power source.

In the semiconductor light emitting device 141, driver circuits of LEDs are integrated to make it possible to provide a smaller semiconductor light emitting device having high reliability. A photosensor is incorporated in the device to more conveniently feedback an amount of light. An operation temperature or the like is monitored to make it possible to realize a high-efficient operation. A semiconductor light emitting device having, in addition to an illuminating function, a data communication function can be provided. In this manner, a driving circuit of an LED and other functional circuits can be integrated on a substrate on which an LED is manufactured.

According to the embodiment, a light emitting device that does not require a substrate re-covering process and has high productivity and practical light extraction efficiency can be realized. According to the embodiment, in a light emitting device using an Si substrate as a crystal growing substrate, practical light extraction can be realized without executing a substrate bonding/removing process. According to the embodiment, a nitride semiconductor light emitting device can be directly manufactured on a Si substrate. In terms of processes, a reduction in manufacturing cost, a high yield, and high productivity can be expected. In terms of resources, an amount of consumption of an expensive material such as a gold alloy used in substrate bonding can be reduced. In terms of device characteristics, a device having a high thermal resistivity that is almost equal to or more than that of a thin-film type light emitting device can be realized. Furthermore, on an Si substrate, monolithic integration can be easily realized.

In a semiconductor light emitting device according to the embodiment and a method for manufacturing the same, as a method for growing a semiconductor layer, for example, a metal-organic chemical vapor deposition (MOCVD) method, a metal-organic vapor phase epitaxy method, and the like can be used

According to the embodiment, a semiconductor light emitting device having high productivity and high efficiency and a method for manufacturing the same can be provided.

In the specification, the “nitride semiconductor” includes semiconductors having all compositions in which composition ratios x, y, and z are changed within respective ranges in a chemical formula: BₓIn_{y}Al_{z}Ga_{1-x-y-z}N (0≦x≦1, 0≦y≦1, 0≦z≦1, x+y+z≦1). Furthermore, it is assumed that, in the chemical formula, the “nitride semiconductor” also includes a material that further contains a V-group element except for N (nitrogen), a material that further contains various elements added to control various physical properties such as conductivity, and a material that further unintentionally contains various elements.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

The embodiments of the invention have been described above with reference to the specific examples. However, the invention is not limited to the specific examples. For example, as long as persons skilled in the art appropriately selects specific configurations of elements such as a silicon substrate, foundation semiconductor layer, a first semiconductor layer, a second semiconductor layer, a light-emitting unit, a light transmissive electrode, an electrode, and the like included in the semiconductor light emitting device within the known range to similarly execute the invention and obtain the same effects, the specific configurations are included in the spirit and scope of the invention.

Further, any two or more components of the specific examples may be combined within the extent of technical feasibility and are included in the scope of the invention to the extent that the purport of the invention is included.

Moreover, all semiconductor light emitting devices and methods for the same practicable by an appropriate design modification by one skilled in the art based on the semiconductor light emitting devices and the methods for manufacturing the same described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1. A semiconductor light emitting device comprising:
a silicon substrate having a major surface;
a buffer layer provided on a part of the major surface;
a foundation semiconductor layer crystal-grown from an upper surface of the buffer layer, the foundation semiconductor layer covering a non-formed region of the major surface where the buffer layer is not provided, the foundation semiconductor layer being spaced apart from the non-formed region;
a first semiconductor layer of a first conductivity type provided on the foundation semiconductor layer;
a light emitting unit provided on the first semiconductor layer; and
a second semiconductor layer of a second conductivity type provided on the light emitting unit.

2. The device according to claim 1, wherein a ratio of a sectional area of the buffer layer cut along a plane parallel to the major surface to an area of the major surface is larger than 5% and less than 50%.

3. The device according to claim 1, wherein a distance between the major surface of the silicon substrate in the non-formed region and the foundation semiconductor layer is equal to or larger than ⅓ of a peak wavelength of a light emitted from the light emitting unit.

4. The device according to claim 1, wherein a gap and the buffer layer form Total Internal Reflection, the gap being provided between the foundation semiconductor layer and the non-formed region.

5. The device according to claim 1, wherein an impurity concentration in the foundation semiconductor layer is lower than an impurity concentration in the first semiconductor layer.

6. The device according to claim 1, wherein a space between the major surface of the silicon substrate in the non-formed region and the foundation semiconductor layer is in a reduced-pressure state or filled with a gas.

7. The device according to claim 1, further comprising a low-refractive-index layer provided in at least a part of a space between the major surface of the silicon substrate in the non-formed region and the foundation semiconductor layer, the low-refractive-index layer having a refractive index lower than the refractive index of the buffer layer.

8. The device according to claim 1, wherein a refractive index of the buffer layer is lower than a refractive index of the foundation semiconductor layer.

9. The device according to claim 1, wherein
the buffer layer includes a nitride semiconductor including aluminum, and
the foundation semiconductor layer, the first semiconductor layer, the light emitting unit, and the second semiconductor layer include a nitride semiconductor.

10. The device according to claim 1, wherein the non-formed region of the major surface of the silicon substrate is recessed from the part where the buffer layer is provided on the major surface.

11. The device according to claim 1, wherein the buffer layer is continuous, the non-formed region is provided in a plurality, and the plurality of the non-formed regions have an island-like shape.

12. The device according to claim 1, wherein the non-formed region is continuous, the buffer layer is provided in a plurality, and the plurality of buffer layers have an island-like shape.

13. The device according to claim 1, wherein a thickness of a gap provided between the foundation semiconductor layer and the non-formed region is 1 micrometer or less.

14. The device according to claim 1, wherein the buffer layer includes a plurality of first layers and a second layer provided between the first layers, and the second layer has a refractive index different from a refractive index of the first layer.

15. The device according to claim 1, further comprising:
a first electrode;
a light transmissive electrode; and
a light transmissive electrode,
the first semiconductor layer having a first part and a second part arranged with the first part in a direction from the first semiconductor layer toward the second semiconductor layer,
the first electrode being provided on the second part,
the light emitting unit being provided on a first part,
the light transmissive electrode being provided on the second semiconductor layer and being light transmissive to a light emitted from the light emitting unit, and
the second electrode being provided on the light transmissive electrode.

16. The device according to claim 15, wherein a lower surface of a portion facing the non-formed region of the foundation semiconductor layer is located lower than a lower surface of the first electrode.

17. The device according to claim 15, wherein the light transmissive electrode has an unevenness provided on an upper surface of the light transmissive electrode.

18. The device according to claim 15, further comprising:
an electronic circuit provided on the silicon substrate,
at least a part of the electronic circuit is electrically connected to at least one of the first semiconductor layer and the second semiconductor layer.

19. A method for manufacturing a semiconductor light emitting device, comprising:
forming a buffer layer on a part of a major surface of a silicon substrate;
laterally crystal-growing a foundation semiconductor layer from an upper surface of the buffer layer, the foundation semiconductor layer covering a non-formed region where the buffer layer is not provided on the major surface, the foundation semiconductor layer being spaced apart from the non-formed region;
crystal-growing a first semiconductor layer of a first conductivity type on the foundation semiconductor layer;
crystal-growing a light emitting unit on the first semiconductor layer; and
crystal-growing a second semiconductor layer of a second conductivity type on the light emitting unit.

20. The method according to claim 19, wherein
the crystal-growing the foundation semiconductor layer includes forming Total Internal Reflection mirror from a gap and the buffer layer, the gap being provided between the foundation semiconductor layer and the non-formed region.
